(19) United States
(12) Patent Application Publication
(10) Pub. No.: US 2006/0238205 A1
(43) Pub. Date: Oct. 26, 2006

(54) Directional capacitive sensor system and method

(75) Inventor: Mark Francis, Toronto (CA)

Correspondence Address: WALKER & SAKO, LLP;Suite 235, 300 South First Street, San Jose, CA, 95113, US

(73) Assignee: Cypress Semiconductor Corporation, San Jose, CA (US)

(21) Appl. No.: 11/408,367

(22) Filed: Apr. 21, 2006

Related U.S. Application Data
(60) Provisional application No. 60/674,066, filed on Apr. 22, 2005.

(51) Int. Cl. G01R 27/26

(52) U.S. Cl. 324/658

(57) ABSTRACT

A capacitive sensing system (200) can include a sense section (202) and a filter section (206). Sense section (202) can activate logic outputs based on a sensed capacitance from sensors (210-1 and 210-2). A filter section (206) can logically combine logic outputs in different ways to generate output signals (INT_{—}1 and INT_{—}2). According to output signals (INT_{—}1 and INT_{—}2), different types of movement in a capacitive body (212) can be detected.

This application claims the benefit of U.S. provisional patent application Ser. No. 60/674,066, filed Apr. 22, 2005.

### TECHNICAL FIELD

The present invention relates generally to electronic sensor switches, and in particular to sensors that provide indications based on a change in capacitance.

### BACKGROUND OF THE INVENTION

Sensor switches can be utilized to detect the movement of an object, and can enjoy a wide variety of applications from security of physical locations to input interfaces of consumer electronic devices.

One type of sensor switch is a reed switch. A reed switch relies on a magnetic field to control a mechanical connection that completes an electric circuit. If there is movement that decreases the magnetic field, the electric connection can change, and activate trigger signal (e.g., alarm). Thus, a reed switch is an electromechanical switch with make or break contacts. Reed switches enjoy wide use as door and window sensors used in home and commercial security systems. Home and commercial home security sensors typically use a reed switch and a magnet either directly wired to a sensor monitor or to a radio frequency (RF) device transmitting device that can report status of the sensors back to a control monitoring station.

Disadvantages of reed type switches can be prone to failure, especially over time. Further, replacement cost can be high, as typically a technician is sent out to replace a failed switch. Further, in many cases, reed relay contacts can be prone to sticking either an open or closed position and require regular vibration to loosen them, otherwise such switches can become jammed and require replacement. Because they form part of an electric circuit, conventional reed switch arrangements require a small current to be passed through the contacts which is not power efficient and the contacts can be prone to corrosion increasing the circuit's impedance and failure.

A second type of sensor switch is a capacitive sensor switch. Conventional capacitive switching can be used for sensing in applications where the object is of a known capacitive influence (mass) and direction of movement is not of concern. Conventionally, capacitive sensors can be used as keypads on certain digital music (e.g., MP3) player devices, cooker ceramic hotplates, and industrial capacitive proximity sensors, as but a few examples. In all of these conventional applications, typically one or more sensors are used to detect the magnitude of the object changing the capacitive field. Interpolation can be used between two or more switches to enable potentially higher perceived density of capacitive switches.

In a conventional capacitive sensor switch arrangement, a single sensor can be calibrated and sensor values can be filtered using a time based algorithm to eliminate certain (e.g., erroneous or otherwise invalid) changes from activating a trigger signal. Thus, a conventional capacitive sensor switch can use a single sensor, which could make the circuit susceptible to invalid readings due to movement of other capacitive bodies near the single sensor. Conventional capacitive sensors switches can trip when any body or object comes near to them. So for example, if a conventional capacitive sensing arrangement was utilized for home security, a person adjusting a blind on the window may set off the switch, or a cat on the windowsill may set off the switch, etc. That is, in such a conventional arrangement, a switch can be unable to trip only on the specific motion of opening the window, i.e. the switch lacks ‘intelligence’.

As understood from above, a disadvantage of conventional capacitive sensor switching can include that any fluctuation in the capacitive field can cause the sensor to trigger. This typically makes the use of this type of sensor impractical as a switch in a location where fluctuations in capacitance of similar size to the body being monitored cannot be reliably measured. Practical uses of such sensors can require filtering of the magnitude of the capacitance to see if the object changing the field is the same as the body of interest, opening the potential source of false triggering. As result, there is a greater need specification of detection, and hence cost for monitoring circuit, which will need to have a higher resolution for capacitive sensing.

### BRIEF DESCRIPTION OF THE DRAWINGS

FIG. 1 is a block schematic diagram of a capacitive sensing system according to a first embodiment.

FIG. 2 is a block schematic diagram of a capacitive sensing system according to a second embodiment.

FIG. 3 is a block schematic diagram showing one implementation of user/sense modules according to an embodiment.

FIG. 4 is a block schematic diagram of a capacitive sensing system according to a fourth embodiment.

FIG. 5 is a diagram showing one implementation of look-up table logic according to an embodiment.

FIG. 6 is a flow diagram of a method according to one embodiment.

FIG. 7A to 7D are diagrams showing various sensing examples that can be executed according to one or more of the embodiments.

### DETAILED DESCRIPTION

Various embodiments of the present invention will now be described in detail with reference to a number of drawings. The embodiments show capacitance sensing arrangements that can that can sense both the type and nature of movement in a body within the proximity of multiple capacitive sensors.

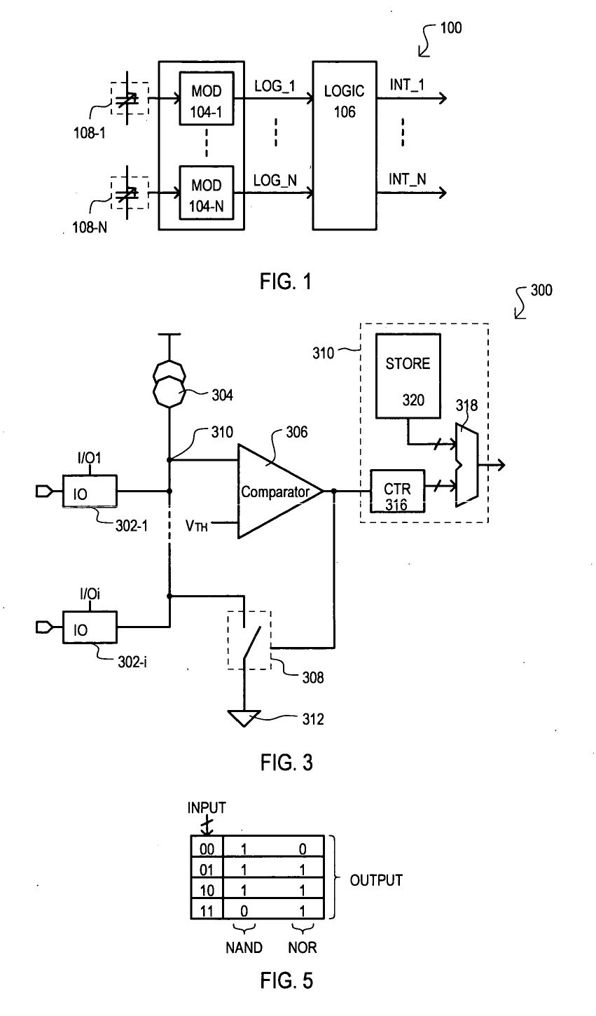

A capacitive sensing system according to a first embodiment is set forth in FIG. 1, and designated by the general reference character 100. A system 100 can include a number of inputs 102-1 to 102-N, capacitance sense modules 104-1 to 104-N, and a logic combination section 106. Each input (102-1 to 102-N) can be connected to a corresponding capacitive sensors (108-1 to 108-N) can provide a change in capacitance in response to a change in the electric field induced by a foreign body.

Each capacitance sense module (104-1 to 104-N) can generate a capacitance logic output value (LOG_1 to LOG_N) based on a capacitance at the corresponding input (102-1 to 102-N). In particular, a capacitance sense module (104-1 to 104-N) can activate the corresponding logic output value (i.e., drive it either high or low) when a sensed capacitance falls outside some predetermined limit. Such a limit may be static (i.e., a high limit and/or low limit) or dynamic (change in value over time), and include hysteresis (i.e., de-activation of a logic output value in response to a different type of change than that required for activation).

A logic combination section 106 can logically combine multiple logic output values in two or more different ways, to generate multiple trigger indications (INT_1 to INT_N). Information presented by such multiple trigger indications can identify type and nature of movement detected by capacitive sensors (108-1 to 108-N).

In this way, multiple capacitive sensor indications can be logically combined to provide indications for determining the type of input event sensed.

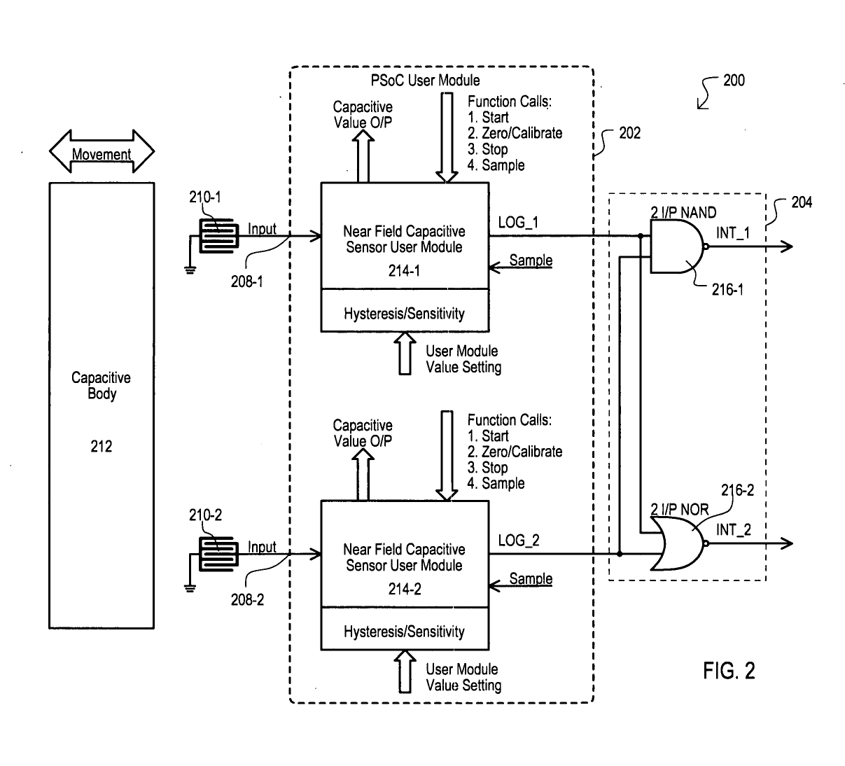

A more detailed embodiment will now be described with reference to FIG. 2. FIG. 2 is a block schematic diagram showing a capacitive sensing system 200 that includes a sense section 202, and a filter section 204. In the particular example of FIG. 2, a sense section 202 can receive capacitance input values at inputs 208-1 and 208-2 from sensors 210-1 and 210-2. Sensors (210-1 and 210-2) can vary an input capacitance in response to a capacitive body (e.g., 212) moving in relation to such sensors.

In the embodiment of FIG. 2, a sense section 202 can be a programmable system on a chip conceptualized as including a user module 214-1 and 214-2 corresponding to each input (208-1 and 208-2). Each user module (214-1 and 214-2) can receive a capacitance via its corresponding input, and generate a capacitance value. Further, a logic value (LOG_1 and LOG_2) can be output from a user module (214-1 and 214-2) based on the sensed capacitance value and predetermined limits. Predetermined limits can be established according to value settings input by a user, or the like. In FIG. 2, each user module (214-1 and 214-2) can operate according to sensitivity value inputs and hysteresis value inputs. A sensitivity value can indicate how much a capacitance value can vary from a limit before a logic value is activated. A hysteresis value can indicate different limits for activating a logic value versus deactivating the same logic value.

User modules (214-1 and 214-2) can execute a number of functions, including but not limited to “Start”, “Zero/Calibrate”, “Stop” and “Sample”. A Start function can initialize capacitance sense circuits for a capacitance detection operation. A Zero/Calibrate function can acquire a baseline capacitance value. A baseline capacitance value can be capacitance present in the absence of an event to be detected. Looked at in another way, a baseline capacitance value can represent a “zero” value with respect to detecting a change in capacitance. A Stop function can disable capacitance sensing operations. A Sample function can acquire a capacitance value from a corresponding input, and activate a logic output when such a value is outside of a limit. A Sample function can be periodically called during standard monitoring operations.

As shown, each user module can output a capacitance value “Capacitive Value O/P”. Such a value can be used for additional processing, other than the generation of a binary sense result (i.e., LOG_1 and LOG2). Thus, more complex sense operations based on actual sensed capacitance values can be executed by system 200.

A filter section 204 can receive logic values (LOG_1 and LOG_2) and filter such values to generate output signals INT_1 and INT_2. In the particular example of FIG. 2, filter section 204 can logically combine signals with a NAND function 216-1 to generate output signal INT_1 and with a NOR function 216-2 to generate output signal INT_2. A system 200 can use a software filter to perform NAND and NOR operations on the Boolean states of the sensors. A software filter can execute the NAND and NOR functions via commands executed by a microcontroller rather than with dedicated hardwired logic gates. However, alternate embodiments can include such functions implemented with hard-wired and/or programmable logic. Still further, in other embodiments, filter can include a configurable time constant to filter out the rate of changes in either or both logic values (LOG_1 and LOG_2). This can help reduce false positive readings.

In the embodiment of FIG. 2, a system 200 can provide a capacitive sensor system with auto cancellation that is configurable to reject non-uniform near field fluctuations. A system 200 can utilize two or more sensors (210-1 and 210-2) and a Zero/Calibration function to “zero out” each individual sensors (210-1 and 210-2) to arrive at a “no detect” baseline capacitance value. When all sensors (210-1 and 210-2) have been calibrated a status of each sensor (210-1 and 210-2) can be checked. In the particular embodiment of FIG. 2, this can include a microcontroller issuing commands to check the status of the sensors (Sample function). In this way, each user module (214-1 and 214-2) has the ability to calibrate to a current known capacitance, and the ability to then set a hysteresis band within which the sensor will not trigger. However, when the capacitance changes outside of the band, a logic output value can change.

Timing between the two or more sensors outputs changing can be indicated by the output of a NOR function 216-2 with respect to the output of NAND function 216-1. Thus, a NOR function 216-2 can be used to check if one sensor triggers before the other. A NAND function 216-1 can be used to determine the direction on the body that is changing the near field capacitance. More particularly, changes in a direction perpendicular to a sensor deployment (210-1 and 210-2) can result in an active NAND function output. However, changes in a direction parallel to a sensor deployment (210-1 and 210-2) may not activate a NAND function output.

In this way, a capacitive near field directional switch can be formed with multiple capacitive sensors combined with simple logic and microcontroller instructions (e.g., firmware or software) to determine the nature and type of change in a capacitive field. Such an arrangement can be well suited to a “make or break” type switch where the movement towards or away from the switch of a capacitive body changes the switches state.

While the embodiment of FIG. 2 shows a system 200 having two sensors, this should not be construed as limiting to the invention. Other embodiment can have more than two sensors, and logically combine the outputs of multiples of such sensors, including all such sensors.

Having described the construction and features of the embodiment of FIG. 2, the operation of the system 200 will now be described. In a first step, system 200 can be calibrated and the user modules (214-1 and 214-2) can zero out sensors (210-1 and 210-2). In a second step, a sensitivity and/or hysteresis value can be loaded into both user modules (214-1 and 214-2). Capacitance values can then be sampled. A sampling rate of sensors (210-1 and 210-2) can be a configurable value set according to a particular application.

In a third step, it is assumed that a capacitive body 212 is within a detectable range of sensors (210-1 and 210-2). In the event of a perpendicular movement of the capacitive body 212 with respect to a capacitance sense direction (vertically in FIG. 2), capacitance values would remain the same, and the system 200 would not trigger (i.e., signals INT_1 and INT_2 are not activated). This assumes that the capacitive body is of sufficient size with respect to the positions of sensors (210-1 and 210-2).

If capacitive body 212 moves towards or away from sensors (210-1 and 210-2) (horizontally in FIG. 2), according to a sample time, one or both sensors (210-1 and 210-2) can detect the movement. If both sensors detect movement at the same time, NAND function 216-1 can register the change of state. Such an approach can be used to detect movement of a door or window, for example. However, if a sensed field was changed by an external factor, such as a smaller capacitive body (e.g., human hand), then one sensor may detect the change in field first, and cause NOR function 216-2 to generate a signal prior to NAND function 216-1.

In this way, a system 200 can detect different capacitance field change types utilizing two or more sensors in conjunction with simple logic functions rather than a single sensor employing a complex processing algorithm.

A user module and/or sense module, such as those shown as 214-i and 104-i (where i is an integer) in FIGS. 1 and 2, can take a variety of forms and employ a variety of sensing methods. In a preferred arrangement, such modules can be formed by an analog capacitance sensing circuit included in a microcontroller circuit. More preferably, such modules can be implemented by a PSoC® Mixed Signal Array, manufactured by Cypress Semiconductor Corporation, of San Jose, Calif.

One particular arrangement for providing user/sense modules is shown in FIG. 3, and designated by the general reference character 300. A module 300 can include a number of input/output (IOs) 302-1 to 302-i, a current source 304, a comparator 306, a reset switch 308, and a processing section 310. Each IO (302-1 to 302-i) can connect a capacitance source (e.g., sensor) to a common bus 310 in a multiplexer type fashion. IOs (302-1 to 302-i) can each be controlled by corresponding I/O signals I/O1 to I/Oi. Current source 304 can be connected to common bus 308 and provide a constant current in zero/calibration operations and sample operations. A reset switch 308 can be connected between common bus 310 and a low power supply node 312. Reset switch 308 can be controlled according to an output of comparator 306.

Comparator 306 can have one input connected to common bus 310, a second input connected to a threshold voltage V_{TH} and an output connected to reset switch 308 and processing section 310.

In such an arrangement, module 300 can form a relaxation oscillator corresponding to each input (and hence each sensor) to generate a signal that varies according to the capacitance of the sensor.

Processing section 310 can include a counter function 316, a compare function 318 and a limit function 320. A counter 316 can count transitions at the output of compare function 306 over a set period of time to acquire a count value representative of a capacitance. A compare function 318 can compare an acquired count value with a limit value provided by limit function 320. A limit function 320 can provide limit values to compare function 318 that can vary according to mode. For example, a limit value can be a count value acquired in a zero operation plus and/or a minus some sensitivity value. Further, such a limit value can vary based on a current output of compare function 318 in the event hysteresis values are used.

In this way, multiple sense/user modules can be formed in a multiplexed fashion, by time sharing capacitance sense and evaluation circuits.

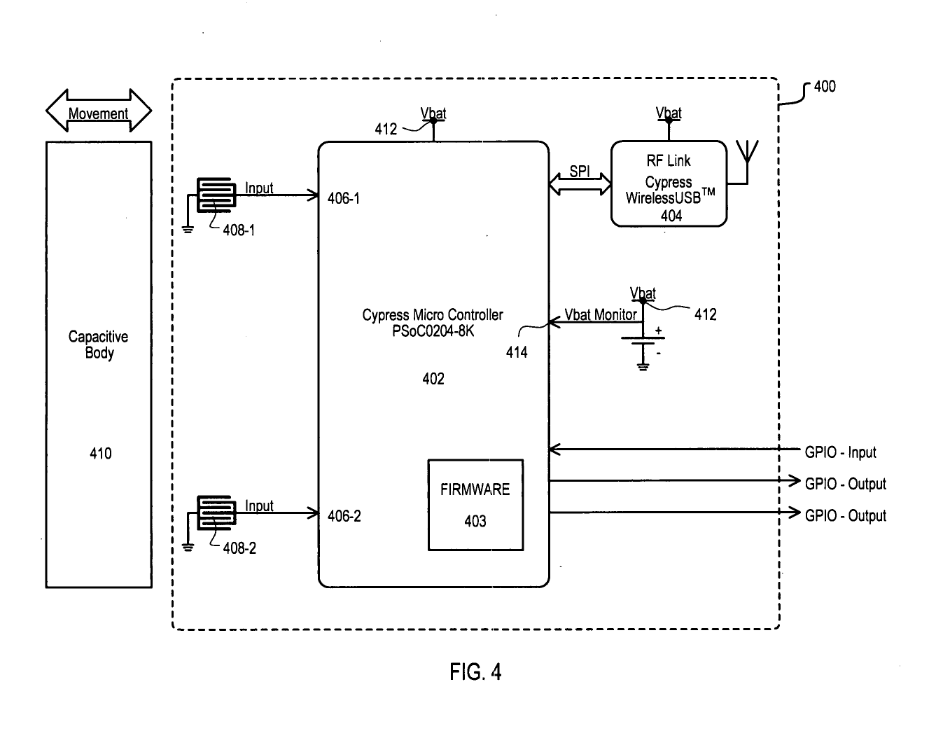

FIG. 4 shows one very particular sensor system 400 according to a third embodiment. Sensor system 400 can include a microcontroller 402 and a wireless link 404. A microcontroller 402 can have inputs 406-1 and 406-2 connected to capacitive sensors 408-1 and 408-2 that can have capacitance values influenced by movement of a capacitive body (e.g., 410). In the arrangement of FIG. 4, microcontroller 402 can be powered by a battery power source 412 and can monitor batter power levels via a power level input 414. Further, a microcontroller 402 can execute a set of instructions stored in firmware 403.

While a microcontroller 402 may take various forms, preferably a microcontroller 402 can be PSoC® microcontroller of Cypress Semiconductor Corporation. Such a microcontroller can advantageously support multiple capacitive sensors in a single device and include hardware for implementing control logic and filtering functions. For example, as shown in FIG. 3 above, such a microcontroller can include an analog system block for executing sense functions. In addition, a microcontroller can use look-up tables (LUTs), or the like, to implement the NAND, NOR or other needed logic functions. Still further, such a microcontroller can include a programmable timer blocks that can measure time between changes of logic outputs (NAND/NOR function outputs).

Accordingly, in the embodiment of FIG. 4, a microcontroller 402 can monitor logic outputs based on a timer, and utilizing software filters and algorithms, can determine a size and/or direction of capacitive body and determine if the change has been caused by the target object being monitored or due to some other event. Based on such monitor results, microcontroller firmware can relay a result, based on additional rules, to other functions and devices in the system. In addition, a microcontroller can monitor capacitive field data (e.g., counts), and filter such results to determine if a capacitive body has moved in a manner sufficient to trigger an indication.

Optionally, a system 400 can include a wireless link 404 connected to microcontroller 402. In such an arrangement, monitor results can be transmitted to some remote location, such as a centralized monitoring station. In the particular example of FIG. 4, a wireless link 404 can be connected via a serial peripheral interface (SPI) and transmit a wireless signal according to a wireless universal serial bus (USB) connection. Of course, the above represents but one particular way of transmitting monitor results.

In addition, a microcontroller 402 can provide outputs values via general purpose input/outputs (GPIO). In a similar fashion, one or more inputs to microcontroller 402, for resetting the system or other purposes, can be provided by one or more GPIOs.

It is noted that while the example of FIG. 4 shows two sensors, the number of sensors could be increased based on the application requirements. Use of multiple sensors can enable a determination of field uniformity and/or a direction of any external factors that change the capacitive field. By adjusting a sensing hysteresis/sensitivity and measuring the time between when one sensor changes to the other, decisions can be made on the type and nature of movement of the body changing the field. By using two or more sensors, simple logic and microcontroller instructions (e.g., firmware) can be calibrated for multiple applications and be calibrated if required for specific environments.

While the embodiments of FIG. 4 shows a microcontroller device for executing monitoring and sensing functions, alternate embodiments can utilize discrete devices or an application specific integrated circuit (IC) under control of a microcontroller, microprocessor, or similar device.

Referring to FIG. 5, an example a LUT that can be utilized to generate NAND/NOR output values based on two sense input values. Such an arrangement can be stored and accessed in a microcontroller to provide a desired logic function. As noted above, this configuration may be readily implemented in a PSoC device.

While embodiments of the present invention can include systems as described above, the present invention may also include methods of sensing capacitance values.

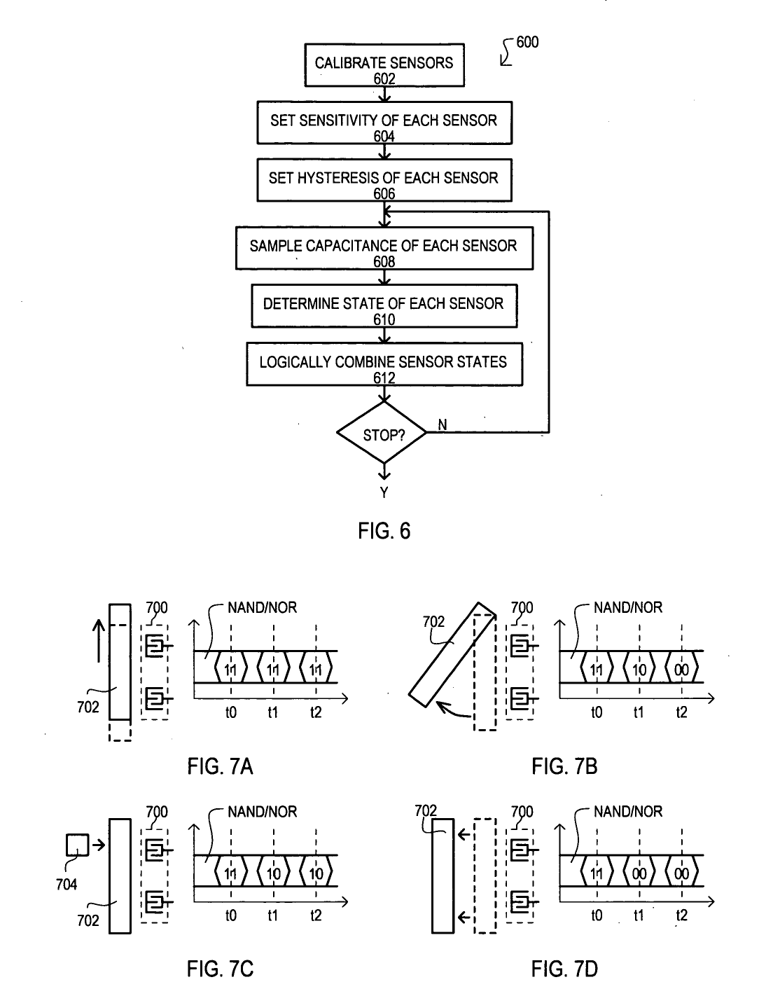

A capacitance sense method according to one embodiment is shown in FIG. 6 and designated by the general reference character 600. A method 600 can include calibrating sensors (step 602). Such a step can include acquiring capacitance values in a non-triggering environment. Even more particularly, such a step can include employing sensors in positions for detecting change, and then zeroing such sensors for the environment (i.e., door closed, window closed, etc.). A method 600 can also include setting a sensitivity for each sensor (step 604). Such a step can include establishing a limit at which a logic output will be triggered for the sensor. This can include programming a trip limit for each sensor according to the application. As but one very particular example, such a step can include acquiring capacitance values when an object in a position at which detection is desired, and utilizing the capacitance to determine a sensing limit.

Optionally, a method 600 can also include setting a hysteresis for each sensor (step 606). Such a step can include establishing different limits at which a logic output will transition from inactive to activate (i.e., triggered) versus the level at which an active signal will return to an inactive state (i.e., reset). This can provide greater stability in detecting a desired field change.

A method 600 can sample capacitance values for each sensor (step 608). Such a step can include acquiring a capacitance value corresponding to each sensor. These values can be acquired essentially simultaneously, in a multiplexed fashion, or some combination thereof. Once capacitance values have been acquired, a state of each sensor can be determined (step 610). Such a step can include comparing a capacitance value to one or more limits. As but one example, a capacitance value for each sensor can be a count value. If a logic signal corresponding to the sensor is inactive, the count value can be checked to see if it is outside a first limit by a predetermined sensitivity value. If this is the case, the signal can be activated. A first limit can be determined by a calibration operation and a hysteresis value. If a logic signal for the sensor is active, and the count value is outside a second limit by a predetermined sensitivity value, the signal can be returned to an inactive state. Such a second limit can also be determined by a zeroing operation and a hysteresis value.

It is understood that a comparison operation can be a greater-than, greater-or-equal-to, less-than, or less-than-or-equal-to, or some combination thereof, as but a few examples. The type of comparison operation will depend upon type of field change to be detected. For example, for many types of capacitive sensors, movement toward a sensor can increase capacitance while movement away from a sensor can decrease capacitance.

A method 600 can further include logically combining sensor states (step 612). Such a logic combination can include combining such values according to more than one type of logic function. As noted above, such a step can include a NAND and NOR function, but can also include other logic functions as well, such as AND and OR, according to the signaling convention used.

In the particular example of FIG. 6, a method 600 can include continuing sense operations unless sensing is to end (step 614).

In this way, a method can sense capacitive body movement based multiple sensors and relatively simple logical operations.

Having described systems and methods according to various embodiments, particular sensing operations will now be described with reference to FIGS. 7A to 7D. Each of FIGS. 7A to 7D shows two sensor positions 700, a capacitive body 702, and a graph. Each graph shows three consecutive samples of NAND/NOR combination of the output states provided by sensors 702.

In FIG. 7A, a capacitive body 702 moves in a direction perpendicular to sensor plate configuration. As a result, logic values remain unchanged at “11” for all sampled times.

In FIG. 7B, a capacitive body 702 moves in rotational direction to sensors 702. When capacitive body starts to move, at sample time t1, logic values change from “11” to “01” detecting an initial change. As capacitive body 702 continues to move, logic values change from “01” to “00”. As will be described below, sensitivity for sensors 702 can be adjusted to enable simultaneous activation of signals.

In FIG. 7C, a capacitive body 702 remains stationary, while a second smaller body 704 moves towards sensors 702. When smaller capacitive body 704 starts to move, at sample time t1, logic values change from “11” to “01” detecting movement of the smaller body, but not a movement of larger body 702. Because body 704 is a smaller body, logic values can stay at “01” and not transition to “00”.

In FIG. 7D, capacitive body 702 moves away from sensors 702. At sample time t1, logic values change from “11” to “00” detecting the movement away from sensors in a first instance.

Of course, FIGS. 7A to 7D are but a few of the possible types of movement that can be detected. Further, even larger numbers of sensors can provide greater sophistication in sensing field change types.

In one particular application, assuming a back and forward motion of a sensed capacitive body with respect to sensor positions, sensors can be calibrated and the hysteresis value for both sensors can be essentially the same. If both sensors tripped within some time value the sensed body would be consider to have moved, a trigger can be activated. Any variance from such a movement, such as the timing of the change on one sensor to the other was out or the magnitude of one sensor was larger than the other then this would result in no change. Such an arrangement can utilize NAND sensing to indicate valid detection and NOR sensing to prevent false sensing.

In another particular application, a body can move in a rotational fashion, such as a hinged window. In such an arrangement, one sensor could change before another, as one edge of the window can move away faster then the other. To detect such rotational movement, both sensors can be calibrated when the window is closed. However, sensor hysteresis can be asymmetrical, such that a sensor that would trigger first would require a larger capacitive change than other sensors. Based on the expected speed at which the window/door can move, we can learn to measure what would be a normal motion for the target object. Variances from normal motion can be subject to activating a trigger.

Advantages of the various embodiments can be greater reliability and robustness than electro-mechanical/magnetic reed switches, conventionally employed as door and window sensors. Capacitive sensors typically have no moving parts and thus are not subject to the same mechanical or contact failures as reed switches. Accordingly, the embodiments can result in lower cost of ownership through lower maintenance costs.

Still further, microcontroller based systems, like that of FIG. 3, can support additional features, such as non binary outputs and anti-tamper features by changing the internal instructions (e.g., firmware), rather than new components. For example, capacitive values (e.g., counts) can be output for more complex sensing algorithm that can detect a tampering of a system.

In addition, in an alternate embodiment, additional filtering and adjustment for the environment could be made by using intelligent firmware that would dynamically self calibrate for nominal operating conditions. For example, in the embodiment of FIG. 2, an instructions set can periodically execute Stop function for all modules. Then, absent any active logic outputs, execute Start and Zero/Calibrate functions to acquire an updated reading for nominal operating condition.

Embodiments of the present invention are well suited to performing various other steps or variations of the steps recited herein, and in a sequence other than that depicted and/or described herein. In one embodiment, such a process is carried out by processors and other electrical and electronic components, e.g., executing computer readable and computer executable instructions comprising code contained in a computer usable medium.

For purposes of clarity, many of the details of the improved solution and the methods of designing and manufacturing the same that are widely known and are not relevant to the present invention have been omitted from the following description.

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of exemplary embodiments of the invention, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Accordingly, while the various aspects of the particular embodiments set forth herein have been described in detail, the present invention could be subject to various changes, substitutions, and alterations without departing from the spirit and scope of the invention.

What is claimed is:

1. A method, comprising:
calibrating a plurality of capacitance measuring circuits, each coupled to a corresponding capacitance sensor, to determine calibration values for the capacitance sensors in a baseline environment;
zeroing out the capacitance sensors with the calibration values to place the capacitance sensors in a non-triggered state absent a change in sensor capacitance from the baseline environment;
configuring at least a sensitivity value for each capacitance sensor, each sensitivity value determining a capacitance change amount that activates a change indication from the capacitance measuring device; and
logically combining change indications from the capacitance measuring devices to activate a trigger indication when an object moves in a particular direction in relation to the capacitance sensors.

2. The method of claim 1, further including:
configuring at least a hysteresis value for each capacitance sensor, each hysteresis value establishing a first limit that activates a change indication from the capacitance measuring device, and a establishing a second limit that de-activates a change indication from the capacitance measuring device.

3. The method of claim 1, wherein:
logically combining change indications from the capacitance measuring devices to prevent activation of a trigger indication when an object moves in a direction perpendicular to the capacitance sensors physical positions.

4. A sensor, comprising:
a first near field capacitive sense circuit having an output that provides a sense indication based on capacitance input value;
a second near field capacitive sense circuit having an output that provides a sense indication based on capacitance input value; and
a detect circuit coupled to the outputs of at least the of the first and second near field capacitive sense circuits that logically combines the sense indications of the first and second near field capacitive sense circuits in at least two different way.

5. The sensor of claim 4, wherein:
the detect circuit logically combines the sense indications with a logical operation selected from the group consisting of a NAND function and an AND function.

6. The sensor of claim 4, wherein:
the detect circuit logically combines the sense indications with a logical operation selected from the group consisting of a NOR function and an OR function.

7. The sensor of claim 6, wherein:
the detect circuit further logically combines the sense indications with a second logical operation selected from the group consisting of a NAND function and an AND function.

8. The sensor of claim 4, wherein:
at least one of the near field capacitive sense circuits activates the sense indication with hysteresis based on changes in the input capacitance value.

9. The sensor of claim 4, wherein:
all of the near field capacitive sense circuits activate the corresponding sense indication with hysteresis based on changes in the input capacitance value.

10. The sensor of claim 4, wherein:
the sense indications are logic signals; and
the detect circuit comprises a logic gate coupled to the outputs of at least the of the first and second near field capacitive sense circuits that logically combines the sense indications.

11. The sensor of claim 4, further including:
a machine readable media storing processing instructions for logically combining sense indications of the near field capacitive sense circuits; and
the detect circuit comprises a processing circuit that executes the processing instructions.

12. The sensor of claim 4, wherein:
the sense indications comprise multi-bit count values.

13. A capacitive sensing method, comprising the steps of:
sensing a capacitance value at each of a plurality of capacitance sensor inputs;
for each capacitance sensor input, activating a corresponding sense signal when the sensed capacitance value is not within a predetermined range;
filtering the sense signals to selectively activate detect signals based on at least two logical combinations of the sense signals.

14. The method of claim 13, wherein:
sensing the capacitance value at each of a plurality of capacitance sensor inputs includes generating a count value corresponding to the rate at which a capacitance at the sensor input can be charged.

15. The method of claim 13, wherein:
filtering the sense signals includes logically combining signals according to any of the logical combinations selected from the group consisting of: ANDing, NANDin, ORing, NORing.

16. The method of claim 13, wherein:
filtering the sense signals includes applying sense signals as input valued to a look-up table.

17. The method of claim 13, wherein:
filtering the sense signals includes activating a detect signal based on a time difference between activations of same sense signal.

18. The method of claim 13, wherein:
filtering the at least one logic output value includes activating a detect signal based on a time difference between activations of different sense signals.

19. The method of claim 13, further including:
transmitting the detect signal via a wireless transmitter.

20. The method of claim 13, further including:
sensing the capacitance value includes generating a count value corresponding to the rate at which a capacitance at the sensor input can be charged; and
activating the detect signal based on changes in count values for different sensor inputs over time.
